(19) United States
(12) Patent Application Publication
(10) Pub. No.: US 2013/0100598 A1
(43) Pub. Date: Apr. 25, 2013

(54) DISPLAY DEVICE

(71) Applicants: Ichiro Umekawa, Osaka (JP); Yoshitsugu Kawahigashi, Osaka (JP)

(72) Inventors: Ichiro Umekawa, Osaka (JP); Yoshitsugu Kawahigashi, Osaka (JP)

(73) Assignee: SHARP KABUSHIKI KAISHA, Osaka (JP)

(21) Appl. No.: 13/805,573

(22) PCT Filed: Apr. 12, 2011
(86) PCT No.: PCT/JP2011/059057

§ 371 Date: Dec. 19, 2012

(30) Foreign Application Priority Data
Jun. 29, 2010 (JP) 2010-147040

(51) Int. Cl. H05K 7/14

(52) U.S. Cl. CPC H05K 7/14
USPC 361/679.01

(57) ABSTRACT

Provided is a display device which can achieve a thickness reduction and allows a panel protection plate to be replaced with ease. The display device is provided with: a liquid crystal display panel (11) having a display surface (11a); and a case (13) having the liquid crystal display panel (11) housed therein. A panel protective plate for protecting the display surface (11a) of the liquid crystal display panel (11) is formed integrally with the case (13).

### TECHNICAL FIELD

The present invention relates to a display device equipped with a display panel.

### BACKGROUND ART

In a conventional display device, main components such as a display panel are housed in a case, and but the case is provided with an opening for display so that a display surface of the display panel inside of the case is exposed to the outside. In order to protect the display surface of the display panel, which is exposed through the opening for display formed in the case, a panel protective plate that was separately prepared is bonded to the display surface of the display panel using an adhesive agent. (See Patent Document 1, for example.)

### RELATED ART DOCUMENT

Patent Document
Patent Document 1: Japanese Patent Application Laid-Open Publication No. 2009-263502

### SUMMARY OF THE INVENTION

### Problems to be Solved by the Invention

When the adhesive agent is interposed between the panel protective plate and the display surface of the display panel, a space between the panel protective plate and the display surface of the display panel is made large, which hinders a thickness reduction of the display device. Further, in a case where the display panel needs to be reused, the adhesive agent makes it difficult to remove the panel protective plate from the display surface of the display panel. Even if it was possible to remove the panel protective plate from the display surface of the display panel, the display surface of the display panel may be damaged, or part of the adhesive agent may be left on the display surface of the display panel.

The present invention was made to solve the above-mentioned problems, and is aiming at providing a display device that can achieve thickness reduction and that allows a panel protective plate to be replaced with ease.

### Means for Solving the Problems

In order to achieve the above-mentioned object, a display device according to one aspect of the present invention includes: a display panel having a display surface; and a case that houses the display panel, wherein the case has a panel protective plate integrally formed therewith, the panel protective plate being provided for protecting the display surface of the display panel. It should be noted that the panel protective plate is integrally formed with the case, and is not attached to the case as a separate component.

In the display device according to one aspect of the present invention, as described above, the panel protective plate, which is provided to protect the display surface of the display panel, is integrally formed with the case, and thus, the panel protective plate is a part of the case. Therefore, even if the panel protective plate is not bonded to the display surface of the display panel with an adhesive agent, the panel protective plate can be retained in a proper place. Because this eliminates a need to provide an adhesive agent between the panel protective plate and the display surface of the display panel, it is possible to bring the panel protective plate into direct contact with the display surface of the display panel (it is possible to eliminate a space between the panel protective plate and the display surface of the display panel). As a result, the display device can be made thinner for the thickness of an adhesive agent that is no longer interposed between the panel protective plate and the display surface of the display panel.

In the display device according to one aspect of the present invention, the panel protective plate and the display surface of the display panel are not bonded to each other by an adhesive agent. This makes it easier to replace the panel protective plate. Also, it is possible to prevent the display surface of the display panel from being damaged when replacing the panel protective plate. It is apparent that the problem of residue of the adhesive agent on the display surface of the display panel does not occur, because no adhesive agent is used. The replacement of the panel protective plate can be done by replacing the entire case.

Further, in the display device according to one aspect of the present invention, because the panel protective plate is integrally formed with the case, it is not necessary to prepare the panel protective plate as a separate component, which allows a reduction in number of components.

If the display device according to one aspect of the present invention is configured such that the display panel has a touch panel function, an outer surface of the panel protective plate (surface on a side opposite to the display panel) serves as a touch input operation surface. In such a case, by bringing the panel protective plate into direct contact with the display surface of the display panel (by eliminating a space between the panel protective plate and the display surface of the display panel), response speed to touch input operations can be improved.

It is preferable that the display device according to one aspect of the present invention be configured such that the case is a box-shaped component constituted of an upper surface and a side portion that is formed in the periphery of the upper surface so as to be perpendicular thereto, the display surface of the display panel housed in the case faces the upper surface of the case, the upper surface of the case has, as a part thereof, a superimposed section that covers the display surface of the display panel entirely, and the superimposed section that is a part of the case serves as the panel protective plate. With this configuration, it is possible to obtain a case that can house the display panel and that integrally has the panel protective plate in a simple manner. A region surrounded by the upper surface and the side portion is the housing region of this case.

In the configuration in which the superimposed section, which is a part of the case, serves as the panel protective plate, it is preferable that the superimposed section of the case be transparent, and other parts of the case than the superimposed section be colored. With this configuration, even when the superimposed section, which is a part of the case, is used as the panel protective plate, an image displayed on the display surface of the display panel can be viewed through an outer surface (surface on the side opposite to the display panel) of the superimposed section of the case. Also, because the other parts of the case than the superimposed section are colored, it is possible to prevent light from leaking through the other parts of the case than the superimposed section.

In the display device according to one aspect of the present invention, it is more preferable that the display surface of the display panel be in direct contact with the panel protective plate integrally formed with the case, having no intermediate agent interposed therebetween. With this configuration, a space between the panel protective plate and the display surface of the display panel can be eliminated, thereby making it possible to reduce the thickness of the display device with ease. In a case where the display panel is provided with a touch panel function, that is, when the outer surface of the panel protective plate (surface on the side opposite to the display panel) serves as a touch input operation surface, the response speed to touch input operations can be improved with ease.

In the display device according to one aspect of the present invention, it is preferable that the display device be further provided with a pressing member disposed on the display panel on a side opposite to the display surface, and that the display panel is pressed toward the panel protective plate by the pressing member. With this configuration, it is possible to reliably bring the panel protective plate and the display surface of the display panel into direct contact with each other. Even when the display panel is pressed toward the panel protective plate, the panel protective plate does not come off because the panel protective plate is formed integrally with the case.

In the configuration in which the pressing member is provided to the display panel on the side opposite to the display surface, it is preferable that the pressing member be formed of a cushion material. When the pressing member is made of a cushion material, the pressing member can be elastically deformed, which makes it easier to press the display panel with the pressing member.

In the configuration in which the pressing member is provided on the display panel on the side opposite to the display surface, the display device may be further provided with an illumination device disposed on the display panel on the side opposite to the display surface. In such a case, it is preferable that the pressing member be disposed on the illumination device on the side opposite to the display panel. With this configuration, the display panel is pressed by the pressing member indirectly through the illumination device. Therefore, even when the illumination device is disposed on the display panel on the side opposite to the display surface, it is possible to reliably bring the panel protective plate and the display surface of the display panel into direct contact with each other.

In the display device according to one aspect of the present invention, the display panel may have a touch panel function. In this configuration, the outer surface of the panel protective plate (surface on the side opposite to the display panel) serves as a touch input operation surface, and by bringing the panel protective plate and the display surface of the display panel into direct contact with each other (by eliminating a space between the panel protective plate and the display surface of the display panel), the response speed to touch input operations can be improved.

### Effects of the Invention

As described above, according to the present invention, it is possible to achieve the thickness reduction and to allow the panel protective plate to be replaced with ease.

### BRIEF DESCRIPTION OF THE DRAWINGS

FIG. 1 is a cross-sectional view of a display device of Embodiment 1 of the present invention.

FIG. 2 is a perspective view (from the outer surface side) of a case used in the display device shown in FIG. 1.

FIG. 3 is a perspective view (from the inner surface side) of the case used in the display device shown in FIG. 1.

FIG. 4 is a diagram for illustrating a location to place a pressing member (spacer made of a cushion material) used in the display device shown in FIG. 1.

FIG. 5 is a cross-sectional view of a display device of Embodiment 2 of the present invention.

FIG. 6 is a cross-sectional view of a display device of Embodiment 3 of the present invention.

### DETAILED DESCRIPTION OF EMBODIMENTS

### Embodiment 1

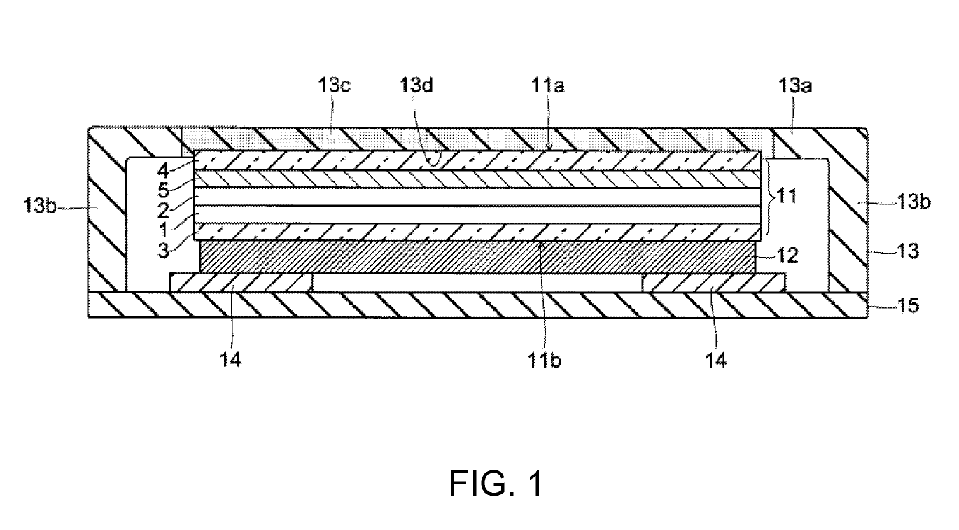

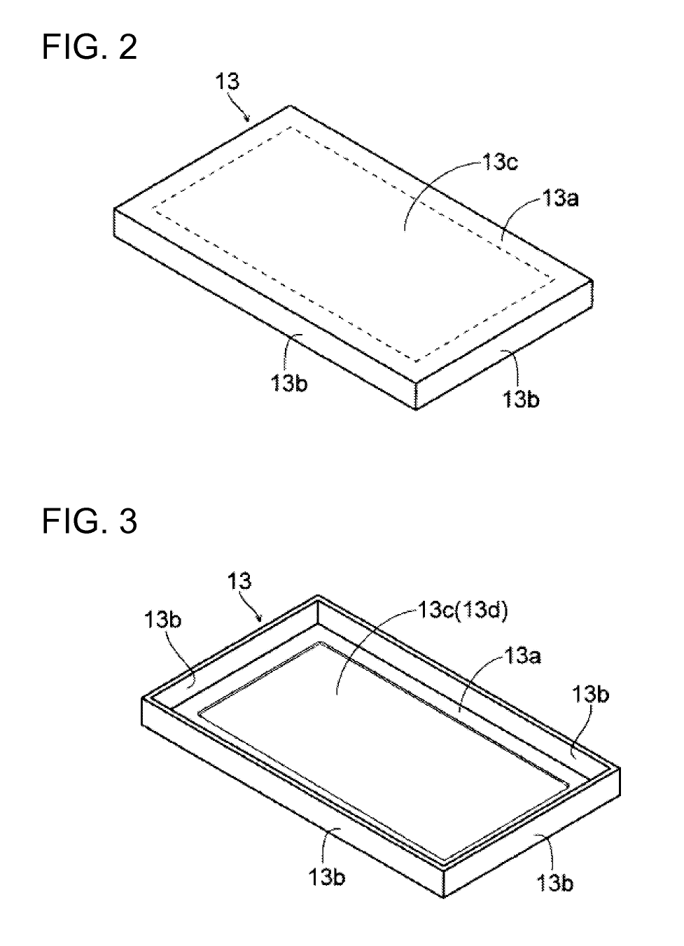

First, with reference to FIGS. 1 to 4, a configuration of a display device according to Embodiment 1 will be explained.

The display device of Embodiment 1 is a liquid crystal display device built into an electronic device such as a mobile phone. The display device at least includes a liquid crystal display panel 11 having a display surface 11a for displaying an image and a backlight unit 12 disposed on a rear surface 11b of the liquid crystal display panel 11, which is the side opposite to the display surface 11a. The liquid crystal display panel 11 is an example of the “display panel” of the present invention, and the backlight unit 12 is an example of the “illumination device” of the present invention.

The liquid crystal display panel 11 has a display region that actually displays an image and a non-display region in the periphery of the display region. In the display region of the liquid crystal display panel 11, a plurality of pixels are arranged in a matrix.

Each of the plurality of pixels is driven by a switching element, a pixel electrode, a common electrode, and the like. For ease of illustration, switching elements, pixel electrodes, and a common electrode are not shown, and wiring lines connected thereto are not shown.

Each switching element is constituted of a TFT (thin film transistor) having the gate connected to a gate line (scan line) and the source connected to a source line (data line). The drain of each switching element is connected to a pixel electrode, and the common electrode is disposed so as to face respective pixel electrodes. Liquid crystal (not shown) is held between the pixel electrodes and the common electrode.

In the display operation, optical characteristics (light transmittance) of the liquid crystal of the liquid crystal display panel 11 are adjusted in each pixel, and the rear surface 11b of the liquid crystal display panel 11 is illuminated by light from the backlight unit 12. This way, the transmittance of the backlight that passes through the liquid crystal display panel 11 is made to differ in each pixel, thereby allowing the liquid crystal display panel 11 to display a desired image on the display surface 11a.

Upon start of the display operation, in the liquid crystal display panel 11, power is supplied to the pixel electrodes through the switching elements, thereby generating electrical fields between the pixel electrodes and the common electrode. As a result of the electrical fields generated between the pixel electrodes and the common electrode, the orientation of the liquid crystal, that is, the optical characteristics (light transmittance) of the liquid crystal are changed.

The liquid crystal display panel 11 has a touch panel function. That is, a prescribed surface of the liquid crystal display device, which is exposed to the user's side (the side from which a displayed image on the display surface 11a of the liquid crystal display panel 11 can be viewed), serves as a touch input operation surface, and when the touch input operation surface is touched (pressed) by a finger or a pen, information based on the touch position is inputted to an information processing section. As described in detail below, a touch position detection section that is provided to detect a touch position is integrally formed with the liquid crystal display panel 11.

Below, the structure of the liquid crystal display panel 11 will be explained in detail.

The liquid crystal display panel 11 at least includes two transparent substrates 1 and 2 (such as glass substrates or plastic substrates, for example).

On a prescribed surface of one transparent substrate 1, the above-mentioned gate lines (scan lines) and source lines (data lines) are formed, in addition to the above-mentioned switching elements and pixel electrodes. On a prescribed surface of the other transparent substrate 2, the above-mentioned common electrode is formed. On the prescribed surface of the other transparent substrate 2, in addition to the common electrode, a color filter may be formed as necessary. The respective prescribed surfaces of the two transparent substrates 1 and 2 are covered by alignment films (not shown) that control the orientation direction of the liquid crystal.

The two transparent substrates 1 and 2 are bonded to each other through a sealing member (not shown) such that the respective prescribed surfaces face each other. Liquid crystal is sealed between the two transparent substrates 1 and 2. This way, the liquid crystal is interposed between the pixel electrodes and the common electrode (between an alignment film covering the prescribed surface of one transparent substrate 1 and an alignment film covering the prescribed surface of the other transparent substrate 2).

One transparent substrate 1 is referred to as an active matrix substrate, and the other transparent substrate 2 may be referred to as a color filter substrate, or may be referred to as an opposite substrate because this substrate is disposed opposing to the transparent substrate 1. In the descriptions below, in order to distinguish the two substrates with ease, the transparent substrate 1, which is one of the two, is referred to as an active matrix substrate 1, and the transparent substrate 2, which is the other of the two, is referred to as a color filter substrate 2.

On a surface of the active matrix substrate 1 on the side opposite to the prescribed surface (surface facing the liquid crystal), a rear polarizing plate 3 is provided. The rear polarizing plate 3 allows the passage of optical waves that vibrate in a specific direction only. On a surface of the color filter substrate 2 on the side opposite to the prescribed surface (surface facing the liquid crystal), a front polarizing plate 4 is provided. The front polarizing plate 4 allows the passage of optical waves that vibrate in a specific direction only. The respective transmission axes of these rear polarizing plate 3 and front polarizing plate 4 differ from each other by approximately 90°. The front polarizing plate 4 is disposed on the surface of the color filter substrate 2 on the side opposite to the prescribed surface (surface facing the liquid crystal), but between the color filter substrate 2 and the front polarizing plate 4, a touch panel electrode 5, which will be later described, is interposed.

In order to realize the touch panel function, the liquid crystal display panel 11 is provided with a touch position detection section formed integrally therewith.

The touch position detection section formed integrally with the liquid crystal display panel 11 employs the capacitance-coupling scheme, and at least includes the touch panel electrode 5 (transparent conductive film made of an ITO film or an IZO film, for example) formed on the surface of the color filter substrate 2 on the side opposite to the liquid crystal (between the color filter substrate 2 and the front polarizing plate 4). The front polarizing plate 4 is attached to the surface of the touch panel electrode 5 on the side opposite to the color filter substrate 2. Although not shown in the figure, in the periphery of the touch panel electrode 5, a plurality of touch position detection electrodes are arranged at certain intervals, and the plurality of touch position detection electrodes are connected to a touch position detection circuit.

The touch position detection operation of the touch position detection section is performed as follows. When the surface of the touch panel electrode 5 on the side facing the front polarizing plate 4 is indirectly touched (pressed), the touch panel electrode 5 is grounded at the touched point through capacitance of the human body. At this time, the capacitance between the respective plurality of touch position detection electrodes and the grounded point is changed, and the change in capacitance is detected by the touch position detection circuit. Then, based on the detection results by the touch position detection circuit, coordinates of the touched position are obtained.

The liquid crystal display panel 11 is configured in the manner described above. The display surface 11a of the liquid crystal display panel 11 is a surface of the front polarizing plate 4 on the side opposite to the touch panel electrode 5.

There is no special limitation on the structure of the backlight unit 12 as long as the rear surface 11b of the liquid crystal display panel 11 can be uniformly illuminated. That is, the backlight unit 12 may be of a direct-lighting type, or may be of an edge-lighting type.

When the backlight unit 12 is of a direct-lighting type, a light source is disposed immediately below the liquid crystal display panel 11. This structure has an advantage in illuminating a large area with high power, and therefore, for a large liquid crystal display device, it is preferable to use a direct-lighting type backlight as the backlight unit 12.

When the backlight unit 12 is of an edge-lighting type, a light guide plate is disposed immediately below the liquid crystal display panel 11, and a light source is disposed so as to face a prescribed side face of the light guide plate. This structure has an advantage in achieving a thinner device, and therefore, for a liquid crystal display device that needs to be made thin, it is preferable to use an edge-lighting type backlight as the backlight unit 12.

The light source of the backlight unit 12 may be a cold-cathode fluorescent lamp, or may be an LED (light-emitting diode). However, when a cold-cathode fluorescent lamp is used as the light source of the backlight unit 12, it is possible that sufficient brightness or life cannot be attained, and further, it is possible that uniform illumination cannot be achieved as a result of the brightness of the lower voltage side being reduced. Therefore, in order to perform high-quality image display, it is preferable to use an LED as the light source of the backlight unit 12.

In addition to the liquid crystal display panel 11 and the backlight unit 12, the liquid crystal display device of Embodiment 1 further includes a case 13 that has a housing region in which those components are housed. The case 13 is made of a resin material such as an ABS resin, a polycarbonate resin, or an acrylic resin, which is generally used for a case of a mobile phone.

As shown in FIGS. 1 to 3, the case 13 has a substantially box-shaped structure that has an upper surface 13a and a side portion 13b formed in the periphery of the upper surface 13a so as to be perpendicular thereto, and a region surrounded by the upper surface 13a and the side portion 13b is the housing region. That is, the liquid crystal display panel 11 and the backlight unit 12 are housed in a region surrounded by the upper surface 13a and the side portion 13b in the case 13. The liquid crystal display panel 11 is placed inside the housing region of the case 13 such that the display surface 11a thereof faces the upper surface 13a of the case 13.

In Embodiment 1, the upper surface 13a of the case 13 does not have an opening for display (opening for exposing the display surface 11a of the liquid crystal display panel 11 housed in the housing region of the case 13). Therefore, in a state in which the liquid crystal display panel 11 is housed in the housing region of the case 13, the entire display surface 11a of the liquid crystal display panel 11 is covered by the upper surface 13a of the case 13. That is, the upper surface 13a of the case 13 has, as a part thereof, a superimposed section 13c that covers the entire display surface 11a of the liquid crystal display panel 11. It should be noted that the superimposed section 13c of the case 13 is a part of the case 13 (part that is integrally formed therewith), and is not attached to the case 13 as a separate component.

In Embodiment 1, instead of separately providing a panel protective plate for protecting the display surface 11a of the liquid crystal display panel 11, the superimposed section 13c of the case 13 is used as the panel protective plate. This means that the panel protective plate is integrally formed with the case 13.

In a conventional configuration, the entire portion of the case 13 would be colored, but in the configuration above, if the entire case 13 is colored, the display light (light emitted from the display surface 11a of the liquid crystal display panel 11) would be blocked by the superimposed section 13c of the case 13, making an image displayed on the display surface 11a of the liquid crystal display panel 11 not viewable. Therefore, in this embodiment, the case 13 is configured such that the superimposed section 13c of the case 13 is transparent, and other parts of the case 13 than the superimposed section 13c (the side portion 13b and a frame portion surrounding the superimposed section 13c) are colored, instead of having the entire portion of the case 13 uniformly colored. That is, the superimposed section 13c of the case 13 allows light to pass through, and at the other parts of the case 13 than the superimposed section 13c (the side portion 13b and a frame portion surrounding the superimposed section 13c), light is blocked.

With this configuration, when an image is displayed on the display surface 11a of the liquid crystal display panel 11, the display light (light emitted from the display surface 11a of the liquid crystal display panel 11) passes through the superimposed section 13c of the case 13, and the image displayed on the display surface 11a of the liquid crystal display panel 11 can be viewed through the outer surface (surface on the side opposite to the liquid crystal display panel 11) of the superimposed section 13c of the case 13. It is apparent that this outer surface of the superimposed section 13c of the case 13 serves as a touch input operation surface in the touch input operation.

In Embodiment 1, a recess 13d is formed on the inner surface (surface facing the liquid crystal display panel 11) of the superimposed section 13c of the case 13 to retain a part of the liquid crystal display panel 11 on the display surface 11a side therein. Therefore, the thickness of the superimposed section 13c of the case 13 is made smaller than that of the other parts of the case 13. The thickness of the superimposed section 13c of the case 13 is set in accordance with the strength of the case 13 and the operability in the touch input operation.

The part of the liquid crystal display panel 11 on the display surface 11a side engages the recess 13d of the case 13, thereby preventing the liquid crystal display panel 11 from moving out of place. When the part of the liquid crystal display panel 11 on the display surface 11a side engages the recess 13d of the case 13, the display surface 11a of the liquid crystal display panel 11 is in direct contact with the inner surface of the recess 13d of the case 13. That is, the inner surface of the superimposed section 13c of the case 13 and the display surface 11a of the liquid crystal display panel 11 are in direct contact with each other having no intermediate agent such as an adhesive agent interposed therebetween. Therefore, the inner surface of the superimposed section 13c of the case 13 and the display surface 11a of the liquid crystal display panel 11 have no space therebetween.

Further, in Embodiment 1, spacers 14 made of a cushion material are disposed on the backlight unit 12 on the side opposite to the liquid crystal display panel 11, and by sandwiching the spacers 14 between the backlight unit 12 and the rear cover 15, the spacers 14 are elastically deformed. This creates a force in the spacers 14 to press the liquid crystal display panel 11 (backlight unit 12) toward the superimposed section 13c of the case 13. The spacer 14 is an example of the “pressing member” in the present invention.

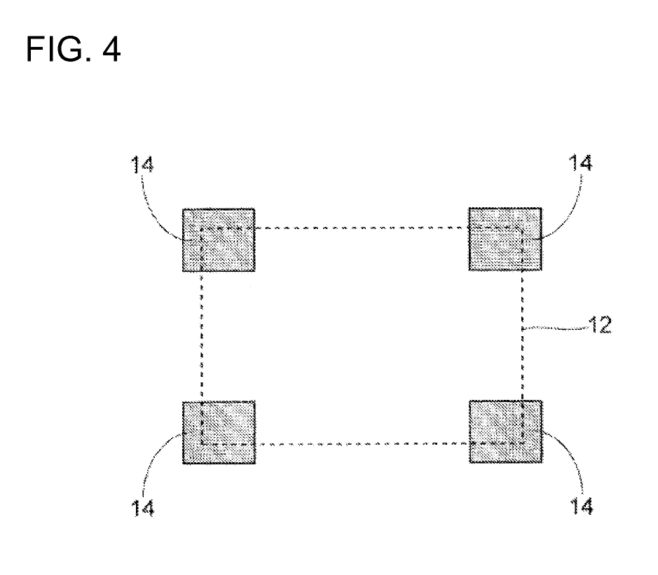

There is no special limitation on the location to place the spacers 14, and for example, as shown in FIG. 4, the spacers 14 are disposed at the four corners of the backlight unit 12. Also, there is no special limitation on the shape of the spacers 14. Examples of the material of the spacers 14 include resin materials such as poron and rubber.

In Embodiment 1, as described above, the superimposed section 13c, which covers the entire display surface 11a of the liquid crystal display panel 11 having a touch panel function, is integrally formed with the upper surface 13a of the case 13, and the superimposed section 13c of the case 13 is used as a panel protective plate. That is, by integrally forming the panel protective plate with the case 13, the panel protective plate is provided as a part of the case 13, and therefore, even if the panel protective plate (the superimposed section 13c of the case 13) is not bonded to the display surface 11a of the liquid crystal display panel 11 by an adhesive agent, the panel protective plate (the superimposed section 13c of the case 13) can be retained in a proper place.

This eliminates a need to provide an adhesive agent between the panel protective plate (the superimposed section 13c of the case 13) and the display surface 11a of the liquid crystal display panel 11, and therefore, it is possible to bring the panel protective plate (the superimposed section 13c of the case 13) into direct contact with the display surface 11a of the liquid crystal display panel 11, which eliminates a space between the panel protective plate (the superimposed section 13c of the case 13) and the display surface 11a of the liquid crystal display panel 11. As a result, the liquid crystal display device can be made thinner for the thickness of an adhesive agent that is no longer provided between the panel protective plate (the superimposed section 13c of the case 13) and the display surface 11a of the liquid crystal display panel 11.

In this embodiment, the outer surface of the panel protective plate (the superimposed section 13c of the case 13) serves as a touch input operation surface. As a result of the panel protective plate (the superimposed section 13c of the case 13) being in direct contact with the display surface 11a of the liquid crystal display panel 11, it is also possible improve the response speed to touch input operations.

Because the panel protective plate (the superimposed section 13c of the case 13) and the display surface 11a of the liquid crystal display panel 11 are not bonded by an adhesive agent, the panel protective plate (the superimposed section 13c of the case 13) can be replaced with ease. In addition, it is possible to prevent the display surface 11a of the liquid crystal display panel 11 from being damaged when replacing the panel protective plate (the superimposed section 13c of the case 13). The replacement of the panel protective plate (the superimposed section 13c of the case 13) can be done by replacing the entire case 13.

Further, because the panel protective plate (the superimposed section 13c of the case 13) is integrally formed with the case 13, it is not necessary to prepare the panel protective plate as a separate component, allowing a reduction in number of components.

In Embodiment 1, as described above, the case 13 is a box-shaped component constituted of the upper surface 13a and the side portion 13b formed in the periphery of the upper surface 13a so as to be perpendicular thereto, and the superimposed section 13c that covers the entire display surface 11a of the liquid crystal display panel 11 is integrally formed with the upper surface 13a of the case 13 such that the superimposed section 13c, which is a part of the case 13, is used as a panel protective plate. With this configuration, it is possible to obtain with ease the case 13 that can house the liquid crystal display panel 11 therein and that has the panel protective plate (the superimposed section 13c of the case 13) formed integrally therewith.

In this case, the case 13 can be configured such that the superimposed section 13c is transparent, and the other parts of the case 13 than the superimposed section 13c (the side portion 13b and the frame portion surrounding the superimposed section 13c) are colored. This way, even when the superimposed section 13c of the case 13 is used as a panel protective plate, it is possible to view an image displayed on the display surface 11a of the liquid crystal display panel 11 through the outer surface of the superimposed section 13c of the case 13 (surface on the side opposite to the liquid crystal display panel 11). Because the other parts of the case 13 than the superimposed section 13c (the side portion 13b and the frame portion surrounding the superimposed section 13c) are colored, it is possible to prevent light from leaking through the other parts of the case 13 than the superimposed section 13c (the side portion 13b and the frame portion surrounding the superimposed section 13c).

In Embodiment 1, as described above, the spacers 14 made of a cushion material are disposed on the side opposite to the display surface 11a of the liquid crystal display panel 11 (on the backlight unit 12 on the side opposite to the liquid crystal display panel 11). The spacers 14 made of a cushion material can be elastically deformed, thereby serving as pressing members that press the liquid crystal display panel 11 toward the panel protective plate (the superimposed section 13c of the case 13). This makes it possible to reliably bring the panel protective plate (the superimposed section 13c of the case 13) and the display surface 11a of the liquid crystal display panel 11 into direct contact with each other.

Even when the liquid crystal display panel 11 is pressed toward the panel protective plate (the superimposed section 13c of the case 13), the panel protective plate (the superimposed section 13c of the case 13) does not come off because the panel protective plate (the superimposed section 13c of the case 13) is formed integrally with the case 13.

Although the backlight unit 12 is disposed on the liquid crystal display panel 11 on the side opposite to the display surface 11a, the spacers 14 can press the liquid crystal display panel 11 indirectly through the backlight unit 12, and therefore, the presence of the backlight unit 12 does not cause a problem.

### Embodiment 2

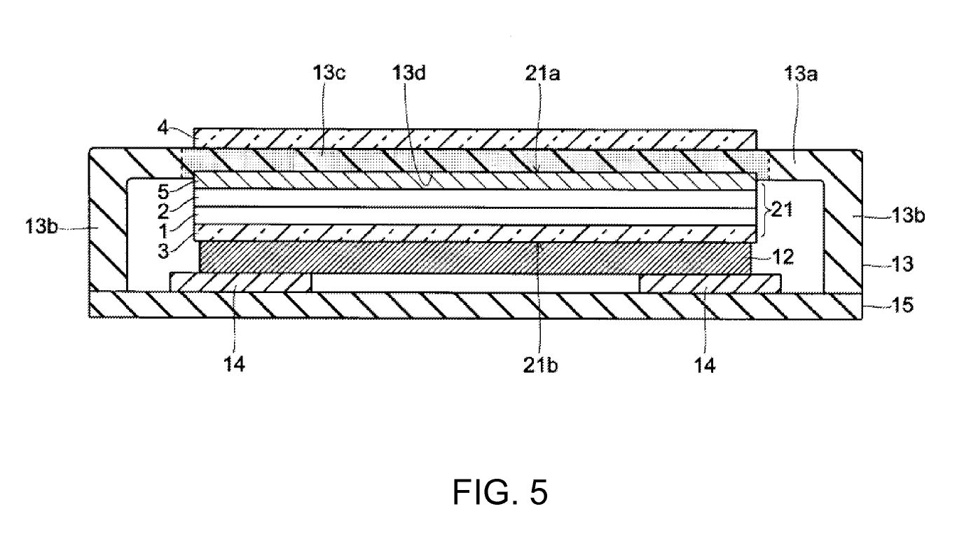

Next, with reference to FIG. 5, a configuration of a display device according to Embodiment 2 will be explained. The same reference characters are given to components that have the same functions as those of the components used in Embodiment 1, and the detailed descriptions thereof are omitted.

Similar to Embodiment 1, the display device of Embodiment 2 is a liquid crystal display device, and as shown in FIG. 5, at least includes a liquid crystal display panel 21 having a display surface 21a and a backlight unit 12 disposed on a rear surface 21b of the liquid crystal display panel 21. The liquid crystal display panel 21 is equipped with a touch panel function.

The liquid crystal display panel 21 has a structure in which liquid crystal is held between an active matrix substrate 1 and a color filter substrate 2. A rear polarizing plate 3 is attached to a surface of the active matrix substrate 1 on the side opposite to the liquid crystal, and a touch panel electrode 5 is formed on a surface of the color filter substrate 2 on the side opposite to the liquid crystal.

Embodiment 2 differs from Embodiment 1 in that a front polarizing plate 4 is not attached to a surface of the touch panel electrode 5 on the side opposite to the color filter substrate 2, and the front polarizing plate 4 is separated from the liquid crystal display panel 21.

That is, in Embodiment 2, the surface of the touch panel electrode 5 on the side opposite to the color filter substrate 2 serves as the display surface 21a of the liquid crystal display panel 21. The surface of the touch panel electrode 5 on the side opposite to the color filter substrate 2 is covered by the superimposed section 13c of the case 13, and is in direct contact with the inner surface of the superimposed section 13c of the case 13 with no intermediate agent (such as an adhesive agent) interposed therebetween. The front polarizing plate 4 that is separated from the liquid crystal display panel 21 is attached to the outer surface of the superimposed section 13c of the case 13.

In Embodiment 2, in a manner similar to Embodiment 1, spacers 14 are formed on the backlight unit 12 on the side opposite to the liquid crystal display panel 21, and the spacers 14 are pressing the liquid crystal display panel 21 toward the superimposed section 13c of the case 13.

Although the structure of the liquid crystal display panel 21 of Embodiment 2 is slightly different from the structure of the liquid crystal display panel 11 of Embodiment 1, effects similar to those of Embodiment 1 can be obtained.

### Embodiment 3

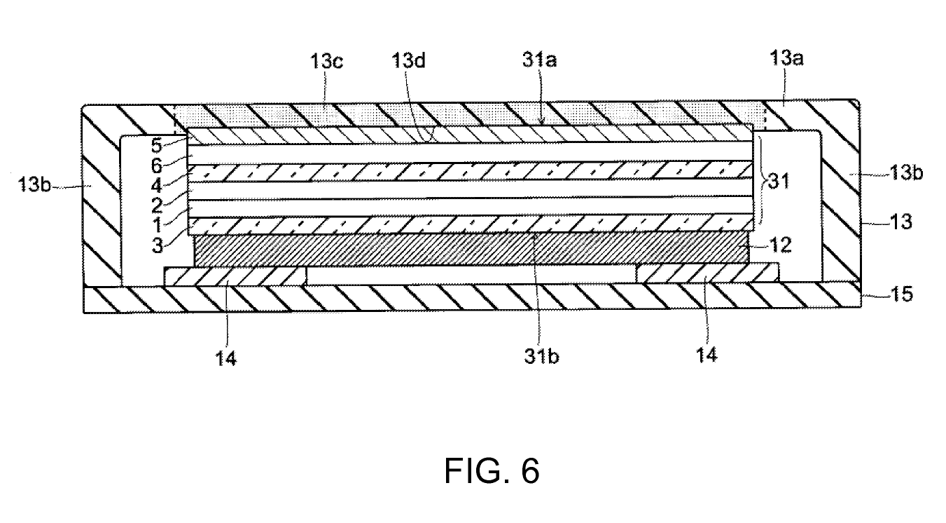

Next, with reference to FIG. 6, a configuration of a display device according to Embodiment 3 will be explained. The same reference characters are given to components that have the same functions as those of the components used in Embodiment 1, and the detailed descriptions thereof are omitted.

Similar to Embodiment 1, the display device of Embodiment 3 is a liquid crystal display device, and as shown in FIG. 6, at least includes a liquid crystal display panel 31 having a display surface 31a and a backlight unit 12 disposed on a rear surface 31b of the liquid crystal display panel 31. The liquid crystal display panel 31 is equipped with a touch panel function.

The liquid crystal display panel 31 has a structure in which liquid crystal is held between an active matrix substrate 1 and a color filter substrate 2. A rear polarizing plate 3 is attached to a surface of the active matrix substrate 1 on the side opposite to the liquid crystal, and a front polarizing plate 4 is attached to a surface of the color filter substrate 2 on the side opposite to the liquid crystal.

Embodiment 3 differs from Embodiment 1 in that a transparent substrate 6 for a touch panel is disposed on a surface of the front polarizing plate 4 on the side opposite to the color filter substrate 2, and a touch panel electrode 5 is disposed on a surface of the transparent substrate 6 on the side opposite to the front polarizing plate 4. A surface of the touch panel electrode 5 on the side opposite to the transparent substrate 6 serves as the display surface 31a of the liquid crystal display panel 31. The surface of the touch panel electrode 5 on the side opposite to the transparent substrate 6 is covered by the superimposed section 13c of the case 13, and is in direct contact with the inner surface of the superimposed section 13c of the case 13 with no intermediate agent (such as an adhesive agent) interposed therebetween.

In Embodiment 3, in a manner similar to Embodiment 1, spacers 14 are formed on the backlight unit 12 on the side opposite to the liquid crystal display panel 31, and the spacers 14 are pressing the liquid crystal display panel 31 toward the superimposed section 13c of the case 13.

Although the structure of the liquid crystal display panel 31 of Embodiment 3 is slightly different from the structure of the liquid crystal display panel 11 of Embodiment 1, effects similar to those of Embodiment 1 can be obtained.

The embodiments disclosed herein are, in all aspects, illustrative and not limiting. The scope of the present invention is defined by the scope of claims, rather than the descriptions of the embodiments above, and includes all modifications that have equivalent meaning to the scope of claims and that are made without departing from the scope of claims.

For example, in the embodiments above, the present invention was applied to a liquid crystal display device, but the present invention is not limited to such. It is also possible to apply the present invention to a display device other than a liquid crystal display device.

In the embodiments above, the liquid crystal display panel was equipped with a touch panel function, but the present invention is not limited to such, and the liquid crystal display panel does not need to have a touch panel function.

In the embodiments above, the liquid crystal display panel was equipped with a capacitance-coupling type touch position detection section, but the present invention is not limited to such, and the touch position detection section in the liquid crystal display panel does not need to be of a capacitance-coupling type. Examples of other touch panels than the capacitance-coupling touch panel include a resistive touch panel, an infrared touch panel, an ultrasonic touch panel, and an electromagnetic-coupling touch panel.

### DESCRIPTION OF REFERENCE CHARACTERS

11, 21, 31 liquid crystal display panel (display panel)
11a, 21a, 31a display surface
12 backlight unit (illumination device)
13 case
13a upper surface
13b side portion
13c superimposed section (panel protective plate)
14 spacer (pressing member)

1. A display device, comprising:
a display panel having a display surface; and
a case that houses the display panel,
wherein the case has a panel protective plate integrally formed therewith, the panel protective plate being provided for protecting the display surface of the display panel.

2. The display device according to claim 1, wherein the case is a box-shaped component constituted of an upper surface and a side portion that is formed on a periphery of the upper surface so as to be perpendicular thereto, and the display surface of the display panel housed in the case faces the upper surface of the case, and
wherein the upper surface of the case has, as a part thereof, a superimposed section that covers the display surface of the display panel entirely, and the superimposed section that is a part of the case serves as the panel protective plate.

3. The display device according to claim 2, wherein the superimposed section of the case is transparent, and other parts of the case than the superimposed section are colored.

4. The display device according to claim 1, wherein the display surface of the display panel is in direct contact with the panel protective plate that is integrally formed with the case, having no intermediate agent interposed therebetween.

5. The display device according to claim 1, further comprising a pressing member disposed on the display panel on a side opposite to the display surface,
wherein the pressing member presses the display panel toward the panel protective plate.

6. The display device according to claim 5, wherein the pressing member is made of a cushion material.

7. The display device according to claim 5, further comprising an illumination device disposed on the display panel on a side opposite to the display surface,
wherein the pressing member is disposed on the illumination device on a side opposite to the display panel.

8. The display device according to claim 1, wherein the display panel is a display panel having a touch panel function.
